(19) United States
(12) Patent Application Publication
(10) Pub. No.: US 2015/0109063 A1
(43) Pub. Date: Apr. 23, 2015

(54) MAGNETORESISTIVE EFFECT OSCILLATOR

(71) Applicant: TDK CORPORATION, Tokyo (JP)

(72) Inventors: Tsuyoshi SUZUKI, Tokyo (JP); Eiji SUZUKI, Tokyo (JP)

(21) Appl. No.: 14/515,948

(22) Filed: Oct. 16, 2014

(30) Foreign Application Priority Data
Oct. 17, 2013 (JP) 2013-216175
Oct. 7, 2014 (JP) 2014-206104

(51) Int. Cl. H03B 15/00

(52) U.S. Cl. CPC H03B 15/00
USPC 331/107 R

(57) ABSTRACT

A magnetoresistive effect oscillator is provided which is highly endurable against external noise in an initial state. Starting from a state of an operating point of an magnetoresistive effect element being in a region where only a static condition is stabilized, a current applying unit applies a current, which has a first current density not less than a critical current density for oscillation, to the magnetoresistive effect element, and then applies a current having a second current density to the magnetoresistive effect element to make the operating point of the magnetoresistive effect element positioned in a region of bistability such that the magnetoresistive effect element oscillates at a predetermined frequency.

### BACKGROUND

The present invention relates to a magnetoresistive effect oscillator.

A magnetoresistive effect oscillator is an oscillator utilizing precession of magnetization in a magnetic layer of a magnetoresistive effect element, the precession being generated upon application of a current to the magnetoresistive effect element. In recent years, studies on the magnetoresistive effect element have been conducted intensively. Patent Literature (PTL) 1 discloses an operation method of setting an operating point of the magnetoresistive effect element on the basis of a region of bistability, and proposes an operation method of operating the magnetoresistive effect oscillator at a low current density not more than a critical current density for oscillation. In addition, Non Patent Literature (NPL) 1 discloses simulation results of oscillation phenomena in a magnetoresistive effect element.

### CITATION LIST

### Non Patent Literature

[NPL 1] Franchin M et al. “Current driven dynamics of domain walls constrained in ferromagnetic nanopillars” PHYSICAL REVIEW B 78, 054447 2008

### Patent Literature

[PTL 1] Japanese Unexamined Patent Application Publication (Translation of PCT Application) No. 2010-519760

### SUMMARY

According to the operation method disclosed in PTL 1, in an initial state, i.e., a state prior to starting operation for a rise of oscillation, the operating point of the magnetoresistive effect element is set to be positioned in the region of bistability. If an unintended magnetic field, for example, is applied to the magnetoresistive effect element in the region of bistability, the magnetoresistive effect element would be transited from an oscillating condition to a static condition, or transited from a static condition to an oscillating condition, thus resulting in a possibility of malfunction. Hence an oscillation element operating with the operation method disclosed in PTL 1 has the problem that stability is low in the operation as the oscillator element.

The present invention has been made in view of the above-described situation, and an object of the present invention is to provide a magnetoresistive effect oscillator that is highly endurable against external noise and has high stability in an initial state.

To achieve the above object, a magnetoresistive effect oscillator according to a first aspect comprises a magnetoresistive effect element including a first magnetic layer, a second magnetic layer, and a spacer layer sandwiched between the first magnetic layer and the second magnetic layer, and a current applying unit that applies a current to the magnetoresistive effect element to make the magnetoresistive effect element oscillate at a predetermined oscillation frequency, wherein, starting from a state of an operating point of the magnetoresistive effect element being in a region where only a static condition is stabilized, the current applying unit applies a current, which has a first current density not less than a critical current density for oscillation of the magnetoresistive effect element, to the magnetoresistive effect element, and then applies a current having a second current density to the magnetoresistive effect element to make the operating point of the magnetoresistive effect element positioned in a region of bistability such that the magnetoresistive effect element oscillates at a predetermined frequency, a direction of the current having the second current density being same as a direction of the current having the first current density. The magnetoresistive effect oscillator according to the first aspect is highly endurable against external noise in an initial state.

With the present invention, the magnetoresistive effect oscillator can be obtained which has high stability in the initial state.

### BRIEF DESCRIPTION OF THE DRAWINGS

FIG. 1 is a schematic view of a magnetoresistive effect element according to Embodiment 1 of the present invention.

FIG. 2a is a circuit diagram of a magnetoresistive effect oscillator according to each of Embodiments 1 and 2 of the present invention.

FIG. 2b is a circuit diagram of a magnetoresistive effect oscillator according to each of Embodiments 1 and 2 of the present invention.

FIG. 3 is a three-dimensional graph representing an orbit of precession of magnetization in a second magnetic layer of the magnetoresistive effect element according to Embodiment 1 of the present invention.

FIG. 4 is a schematic view of a magnetoresistive effect element according to Embodiment 2 of the present invention.

FIG. 5 illustrates a calculation model for the magnetoresistive effect element according to Embodiment 2 of the present invention.

FIG. 6a is a graph representing the calculation result of a critical current density for oscillation in EXAMPLE 1 of the present invention.

FIG. 6b is a graph representing the calculation result of the critical current density for oscillation in EXAMPLE 1 of the present invention.

FIG. 7a is a graph representing the calculation result of time-dependent change of magnetization near a region of bistability in EXAMPLE 1 of the present invention.

FIG. 7b is a graph representing the calculation result of time-dependent change of magnetization near the region of bistability in EXAMPLE 1 of the present invention.

FIG. 8a is a graph representing an applied current density in EXAMPLE 1 of the present invention.

FIG. 8b is a graph representing the calculation result of a rise of oscillation in EXAMPLE 1 of the present invention.

FIG. 9a is a graph representing an applied current density in EXAMPLE 2 of the present invention.

FIG. 9b is a graph representing the calculation result of a rise of oscillation in EXAMPLE 2 of the present invention.

FIG. 10 is a graph representing a phase diagram of magnetization that causes precession.

### DETAILED DESCRIPTION OF EMBODIMENTS

Exemplary forms for carrying out the present invention are described below with reference to the drawings. The following description discloses some of embodiments of the present invention by way of example, and the present invention is not limited to the embodiments described below. Insofar as embodiments involve the technical concept of the present invention, those embodiments also fall within the scope of the present invention. Individual components, combinations of those components, etc. in the following embodiments are merely illustrative, and addition, omission, replacement, and other alterations of the components are allowed within a scope not departing from the gist of the present invention.

### Embodiment 1

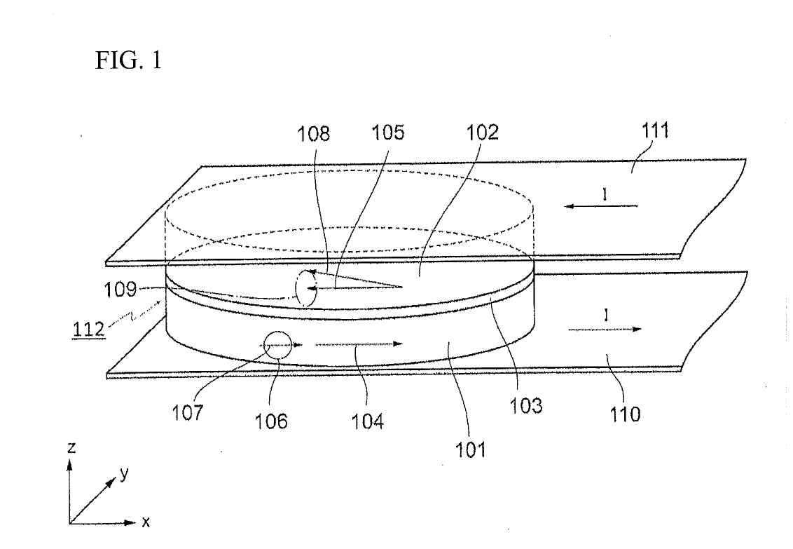

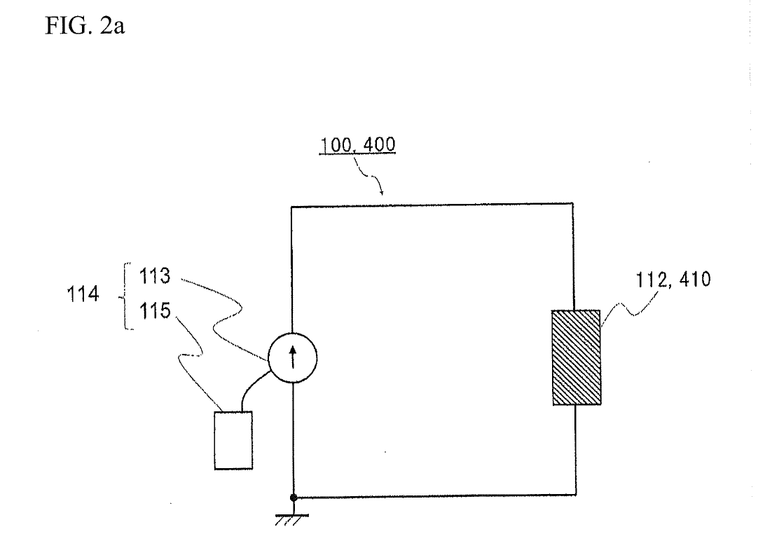

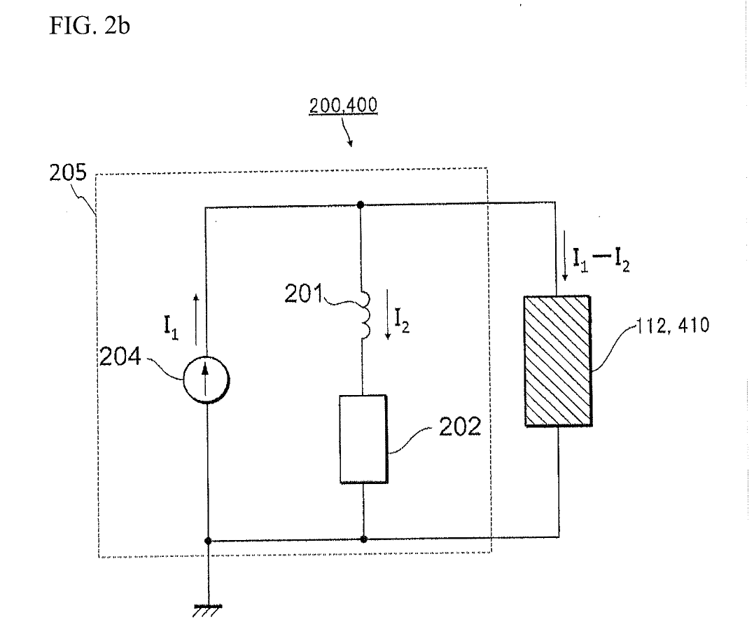

FIG. 2a is a circuit diagram of a magnetoresistive effect oscillator. A magnetoresistive effect oscillator 100 includes a magnetoresistive effect element 112 and a current applying unit 114. The current applying unit 114 includes a current source 113 and a control unit 115. The current source 113 is connected to be able to supply a current to the magnetoresistive effect element 112. The control unit 115 controls the operation of the current source 113. FIG. 1 illustrates an example of configuration of the magnetoresistive effect element 112. The magnetoresistive effect element 112 includes a first magnetic layer 101, a second magnetic layer 102, and a spacer layer 103 arranged between them. The first magnetic layer 101 is in contact with a first electrode 110, and the second magnetic layer 102 is in contact with a second electrode 111, respectively. The current source 113 is connected between the first electrode 110 and the second electrode 111. A direction of magnetization in the first magnetic layer 101 is fixed here, and the fixed direction of magnetization in the first magnetic layer 101 is denoted by an arrow 104. A direction of magnetization in the second magnetic layer 102 is oriented in the direction of an effective magnetic field in a state before application of the current to the magnetoresistive effect element 112, and the direction of the effective magnetic field is denoted by an arrow 105. The effective magnetic field is the sum of an anisotropy magnetic field, an exchange magnetic field, an external magnetic field, and a demagnetizing field, which are generated in the second magnetic layer 102. While the direction of magnetization in the first magnetic layer 101 and the direction of the effective magnetic field in the second magnetic layer 102 are opposed to each other in FIG. 1, those directions are not limited to the illustrated orientations.

Each magnetic layer can be made of, e.g., Fe, Co, Ni, an alloy of Ni and Fe, an alloy of Fe and Co, or an alloy of Fe, Co and B.

The magnetoresistive effect element 112 can be formed of, though not being limited to particular one, e.g., a giant magnetoresistive effect (GMR) element, a tunnel magnetoresistive effect (TMR) element, or a Current-Confined-Path magnetoresistive effect (CCP-GMR) element in which a current-confined-path is present in an insulating layer serving as the spacer layer 103.

In the case of the GMR element, the spacer layer 103 can be made of a nonmagnetic conductive material, such as Cu, Ag, Au or Ru.

In the case of the TMR element, the spacer layer 103 can be made of a nonmagnetic insulating material, such as MgO or AlOx.

In the case of the CCP-GMR element, the insulating layer serving as the spacer layer 103 can be made of, e.g., AlOx or MgO, and the current-confined-path in the spacer layer 103 can be made of nonmagnetic conductive material, such as Cu, Ag, Au or Ru.

The magnetoresistive effect element 112 may include a first intermediate layer. For example, a nonmagnetic metal layer, a magnetic layer, or an insulating layer may be interposed between the first magnetic layer 101 and the spacer layer 103 or between the spacer layer 103 and the second magnetic layer 102.

Furthermore, to fix the direction of magnetization in the magnetic layer, the magnetoresistive effect element 112 may additionally include not only an antiferromagnetic layer in contact with the first magnetic layer 101 or the second magnetic layer 102, but also a second intermediate layer, a third magnetic layer, an antiferromagnetic layer, etc. in contact with the first magnetic layer 101 or the second magnetic layer 102. Alternatively, the direction of magnetization in the magnetic layer may be fixed by utilizing, e.g., magnetic anisotropy attributable to the crystal structure or the shape of the magnetic layer, for example.

The antiferromagnetic layer can be made of, e.g., FeO, CoO, NiO, CuFeS₂, IrMn, FeMn, PtMn, Cr, or Mn.

Moreover, a cap layer, a seed layer, or a buffer layer, for example, may be included between each electrode and each magnetic layer. Those layers can be made of, e.g., Ru, Ta, Cu, or Cr.

In the current applying unit 114, a voltage source, for example, may be connected between the electrodes instead of the current source 113.

In this specification, a current direction is defined as follows. A positive direction is defined as a direction toward the first magnetic layer 101 from the second magnetic layer 102, and a negative direction is defined as a direction toward the second magnetic layer 102 from the first magnetic layer 101.

Oscillation of the magnetoresistive effect element 112 according to this embodiment is described below. Here, the term “oscillation” implies a phenomenon that electrical vibration is induced by a not-vibrational direct current.

The oscillation of the magnetoresistive effect element 112 is generated by dynamics of magnetization in the magnetic layer of the magnetoresistive effect element 112. The dynamics of magnetization can be expressed by the following LLG (Landau-Lifshitz-Gilbert) equation (1).

$$\begin{matrix}[ Math . 1 ] & \\ \frac{\partial v}{\partial t} = - \vert γ \vert ( v \times {II}_{eff} ) + α ( v \times \frac{\partial v}{\partial t} ) + \frac{{μ}_{B} Pj}{e {M}_{S}} v \times ( p \times v ) & ( 1 )\end{matrix}$$

Here, v is a unit vector of magnetization in the second magnetic layer 102, γ is a gyromagnetic ratio, Heff is an effective magnetic field, p is a unit vector of magnetization in the first magnetic layer, α is a Gilbert damping constant, μ_{B} is a Bohr magneton, P is a spin polarization efficiency, j is a current density, e is an elementary charge, M_{S} is a saturated magnetization, d is a thickness of the second magnetic layer 102, and t is a time. The first term in the right side is a precession term, the second term is a damping term, and the third term is a spin-transfer torque term.

When the second magnetic layer 102 can take substantially a single domain structure, motion of the magnetization in the second magnetic layer 102 can be calculated through approximation to a macro magnetization vector. In such a case, the dynamics of magnetization can be calculated by solving the equation (1).

The effective magnetic field is assumed to be the sum of an anisotropy magnetic field Hₖ and a demagnetizing field H_{d}. H_{d} is expressed by the following equation (2).

[Math. 2]

H_{d}=−NM_{S}v (2)

Here, N is a demagnetization factor.

When a current I in the positive direction is applied in a direction perpendicular to a film surface of the magnetoresistive effect element 112, a conduction electron 106 flows in a direction reversed to the direction of the current I, i.e., in a direction toward the second magnetic layer 102 from the first magnetic layer 101 through the spacer layer 103. In the first magnetic layer 101 magnetized in the direction of the arrow 104, a spin of the conduction electron 106 is polarized in the direction of the arrow 104. An arrow 107 represents a spin direction of the conduction electron 106. The electron 106 having the polarized spin flows into the second magnetic layer 102 through the spacer layer 103, whereby transfer of angular momentum is performed with respect to the magnetization in the second magnetic layer 102. This develops an action (represented by the third term in the equation (1)) to change the direction of magnetization in the second magnetic layer 102 from a direction of the arrow 105 that represents the direction of the effective magnetic field. On the other hand, a damping action (represented by the second term in the equation (1)) is also developed to stabilize the direction of magnetization in the second magnetic layer 102 to be oriented in the direction of the arrow 105 that represents the direction of the effective magnetic field. Accordingly, those two actions are balanced, and the magnetization in the second magnetic layer 102 causes precession around the direction of the effective magnetic field. The precession is illustrated as a motion of an arrow 108, which represents the direction of magnetization in the second magnetic layer 102, around the arrow 105 that represents the direction of the effective magnetic field. A locus of the precession of the arrow 108 is denoted by a dotted line 109. Because the direction 108 of magnetization in the second magnetic layer 102 is changed relative to the direction 104 of magnetization in the first magnetic layer 101 at a high frequency, a resistance value of the magnetoresistive effect element 112 is also changed at the high frequency due to the magnetoresistive effect that resistance is changed depending on a relative angle between the direction 108 of magnetization in the second magnetic layer 102 and the direction 104 of magnetization in the first magnetic layer 101. With the change of the resistance value at the high frequency with respect to the current I, there occurs a voltage vibrating in a high-frequency range of about 100 MHz to several tens THz, for example. The direction 104 of magnetization in the first magnetic layer 101 may have an arbitrary direction, such as a direction horizontally extending in a surface of the magnetoresistive effect element or a direction perpendicular to the surface thereof. Furthermore, the direction of the effective magnetic field is not limited to the direction opposed to the direction 104 of magnetization in the first magnetic layer 101, and it may be the same as the direction 104 of magnetization in the first magnetic layer 101, or an arbitrary direction therebetween. However, a relative angle between the direction of the effective magnetic field and the direction 104 of magnetization in the first magnetic layer is preferably as large as possible.

Starting from a condition in a state where neither an external magnetic field nor a current is applied to the magnetoresistive effect element 112, by applying a direct current having a certain magnitude of current density in a state where an external magnetic field having a certain magnitude is applied as the occasion requires, the magnetization in the second magnetic layer 102 starts the precession, and the magnetoresistive effect element 112 causes oscillation. A minimum current density at that time is called a critical current density j_{O} for oscillation, and it is known as being about 10⁷ A/cm². The critical current density for oscillation varies depending on the intensity and the direction of the external magnetic field.

The precession disappears when the applied current is gradually reduced starting from a condition that a current at not less than the critical current density for oscillation is applied to the magnetoresistive effect element 112 in the state where a constant magnetic field is applied as the occasion requires. A maximum current density at that time is called a critical current density j_{S} for stationary. In other words, when a current is applied at not more than the critical current density for stationary, the magnetoresistive effect element 112 does not cause oscillation.

Moreover, when the current density applied to the magnetoresistive effect element 112 is very large, the spin-transfer torque effect causes magnetization reversal that the magnetization in the second magnetic layer 102 is oriented substantially in the same direction as the magnetization in the first magnetic layer 101, whereupon the precession disappears. A minimum current density upon the occurrence of the magnetization reversal is called a critical current density j_{R} for magnetization reversal.

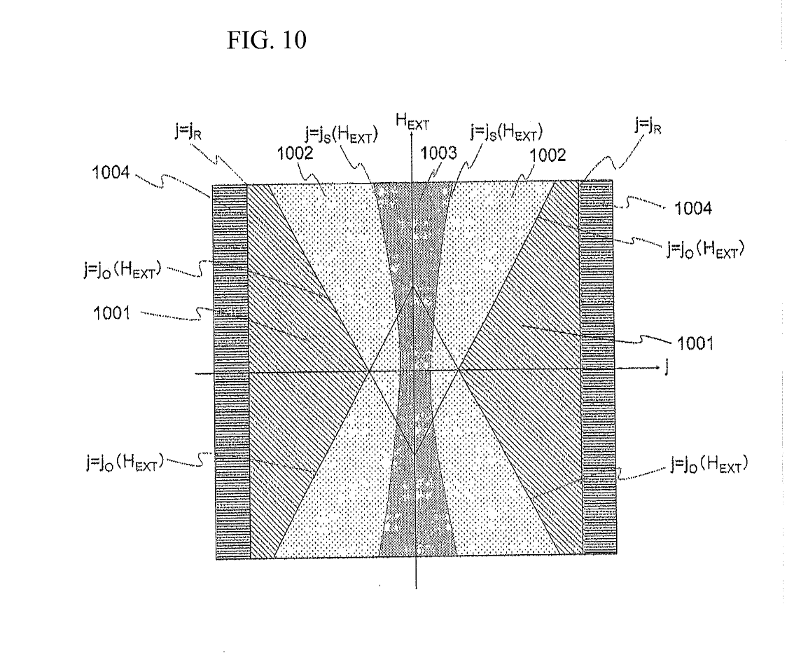

FIG. 10 is one example of a phase diagram of the magnetization (i.e., magnetization that causes precession) in the second magnetic layer 102 of the magnetoresistive effect element 112, the phase diagram being prepared by simplifying that illustrated in PTL 1. In FIG. 10, the horizontal axis denotes a current density j applied to the magnetoresistive effect element 112, and the vertical axis denotes a magnetic field H_{EXT} applied thereto.

A line denoted by j=j_{S}(H_{EXT}) represents dependency of is on a magnetic field. There is a tendency that j_{S} increases as the intensity of the applied magnetic field is increased.

A line denoted by j=j_{O}(H_{EXT}) represents dependency of j_{O} on a magnetic field. There is a tendency that j_{O} increases substantially linearly as the intensity of the applied magnetic field is increased.

A line denoted by j=j_{R} represents that j_{R} is constant regardless of change of the external magnetic field.

A state of the magnetization in the magnetic layer of the magnetoresistive effect element 112 depending on the current density applied to the magnetoresistive effect element 112 is described below, by way of example, on condition that a certain constant magnetic field H_{EXT1} is applied.

When the current density j applied to the magnetoresistive effect element 112 is in the range of j_{R}>j≧j_{O}, the operating point of the magnetoresistive effect element 112 is positioned in a region 1001. In this case, the magnetization in the second magnetic layer 102 causes the precession and only an oscillating condition is stabilized.

When j is in the range of j_{S}≧j, the operating point of the magnetoresistive effect element 112 is positioned in a region 1003. In this case, the precession of the magnetization in the second magnetic layer 102 disappears, and only a static condition (i.e., a condition where the magnetoresistive effect element does not cause oscillation) is stabilized.

When j is in the range of j≧j_{R}, the operating point of the magnetoresistive effect element 112 is positioned in a region 1004. In this case, the magnetization in the second magnetic layer 102 of the magnetoresistive effect element 112 is reversed, and the magnetoresistive effect element 112 is stabilized only in the static condition.

When j is in the range of j_{O}>j>j_{S}, the operating point of the magnetoresistive effect element 112 is positioned in a region 1002. In this case, a stable condition of the magnetization in the second magnetic layer 102 varies depending on the preceding history. More specifically, when the operating point has been transited from the region 1001 to the region 1002, the precession is generated, thus resulting in the oscillating condition. On the other hand, when the operating point has been transited from the region 1003 to the region 1002, the static condition is resulted. Thus, the region 1002 is called a region of bistability.

The following relational formula holds in an Auto-Oscillation model that is obtained by modeling a stable oscillating condition of a general nonlinear oscillation element.

$$\begin{matrix}[ Math . 3 ] & \\ \frac{1}{{p}_{out}} ∝ 1 - \frac{j}{{j}_{o}} & ( 3 )\end{matrix}$$

Here, pₒᵤₜ is an oscillation output.

A method of experimentally determining the critical current density for oscillation is described below. First, the oscillation output pₒᵤₜ in a steady state is measured while the current density applied to the magnetoresistive effect element 112 is changed. The measurement can be performed by utilizing, e.g., a spectrum analyzer or an oscilloscope. Then, the critical current density j_{O} for oscillation can be obtained by plotting the measurement Result on a graph in which the vertical axis denotes 1/pₒᵤₜ and the horizontal axis denotes j, and by determining j, at which 1/pₒᵤₜ=0 is satisfied, through extrapolation, for example. In a current range where the current density of j_{O} or more is applied to the magnetoresistive effect element 112, only the oscillating condition is stabilized.

A method of experimentally determining, with respect to the operating point of the magnetoresistive effect element 112, the region of bistability and the region where only the static condition is stabilized will be described below. The operating point of the magnetoresistive effect element 112 is positioned in the region of bistability when, after applying a current at not less than the critical current density for oscillation to the magnetoresistive effect element 112 and then gradually reducing the current from a steady state little by little, the oscillating condition is obtained in a steady state. On the other hand, when the static condition is obtained instead, the operating point of the magnetoresistive effect element 112 is positioned in the region where only the static condition is stabilized. The region of bistability and the region where only the static condition is stabilized can be experimentally determined by carrying out the above-described trial while the magnetic field is changed.

In this embodiment, the current is applied to the magnetoresistive effect element 112 in order to sustain the oscillation of the magnetoresistive effect element 112.

The operation of the current source 113 controlled by the control unit 115 in this embodiment is described below. In a first step, the current source 113 applies or does not apply, to the magnetoresistive effect element 112, a current having a current density not more than the critical current density j_{S} for stationary such that the operating point of the magnetoresistive effect element 112 is positioned in the region where only the static condition is stabilized. At that time, the magnetization in the second magnetic layer 102 is oriented in the direction 105 of the effective magnetic field. Then, in a second step, the current source 113 applies, to the magnetoresistive effect element 112, a current flowing in the positive direction and having a first current density that is so large as not less than the critical current density j_{O} for oscillation. Then, in a third step, the current source 113 applies, to the magnetoresistive effect element 112, a current flowing in the positive direction and having a second current density j_{2nd} in the range of j_{S}<j_{2nd}<j_{O} such that the magnetoresistive effect element 112 oscillates at a predetermined frequency.

An example of utilizing a peripheral circuit as a means for implementing the above-described current steps, instead of the method of controlling the current source 113, is described below. FIG. 2b is a circuit diagram of a magnetoresistive effect oscillator 200. The magnetoresistive effect oscillator 200 includes a magnetoresistive effect element 112 and a current applying unit 205. The current applying unit 205 includes an inductor 201, a resistance 202, and a current source 204. The magnetoresistive effect element 112 and the inductor 201 are connected in parallel, and the inductor 201 and the resistance 202 are connected in series. Those components arranged in such a way are connected to the current source 204.

When the current source 204 generates a current I₁ having the first current density, an electromotive force is generated in the inductor 201 so as to cancel change of magnetic flux. Accordingly, the current substantially does not flow through the resistance 202, and almost all of the current I₁ flows through the magnetoresistive effect element 112. Thereafter, when time-varying fluctuations in the current I₁ are settled, the electromotive force disappears and a current I₂ flows through the resistance 202 whereas a constant current I₁−I₂ flows through the magnetoresistive effect element 112. Here, respective values of the inductor 201 and the resistance 202 are adjusted such that I₁−I₂ becomes a current having the second current density. Thus, the magnetoresistive effect oscillator 200 can generate the drive current in this embodiment.

A means for experimentally determining the above-described current applying steps is now described. By holding probes in contact with the electrodes 110 and 111 and measuring a voltage between the electrodes in time domain with an oscilloscope, for example, it is possible to estimate time-dependent change of the current, which is applied to the magnetoresistive effect element, and to experimentally determine, e.g., the magnitude and time of a current pulse.

In the first step in this embodiment, the operating point of the magnetoresistive effect element is positioned in the region where only the static condition is stabilized. On the other hand, in PTL 1, the operating point of the magnetoresistive effect element is positioned in the region of bistability. In the case of PTL 1, when the magnetic field or the current applied to the magnetoresistive effect element temporarily varies in the static condition by, e.g., external noise, there is a risk that the magnetoresistive effect element may be transited to the oscillating condition and may sustain the oscillating condition. Thus, the operation method disclosed in PTL 1 has a problem in sustaining the static condition. In contrast, according to this embodiment, in the first step, the operating point of the magnetoresistive effect element 112 is positioned in the region where only the static condition is stabilized. Therefore, even if the above-mentioned fluctuations in the magnetic field or the current are temporarily generated by, e.g., external noise and the magnetoresistive effect element is temporarily transited to the oscillating condition, the oscillation disappears and the static condition continues upon return to the original magnetic field and the original current. Thus, this embodiment is preferable from the viewpoint of ensuring that the magnetoresistive effect element operates more stably in the first step.

Next, the operation of the magnetization in the second magnetic layer 102 in this embodiment is described.

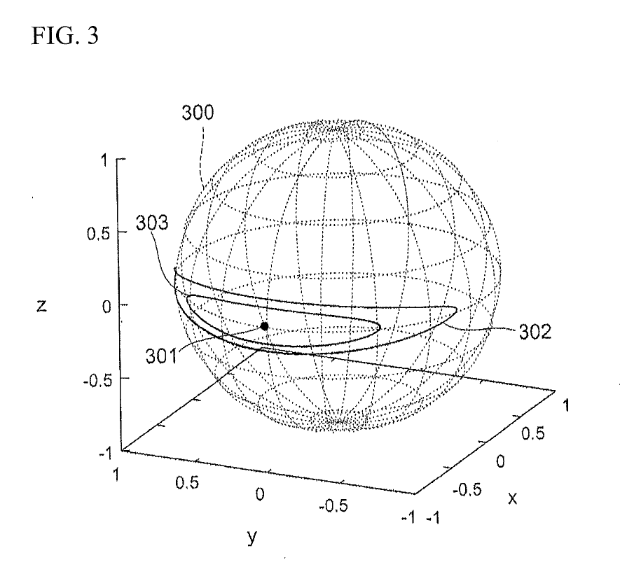

FIG. 3 is a three-dimensional graph representing a locus of a typical magnetization vector in the second magnetic layer 102. Here, axes of an xyz-orthogonal coordinate system are defined such that the direction of the current applied to the magnetoresistive effect element 112 is a negative direction of a z-axis, and that the direction of magnetization in the first magnetic layer 101 in the magnetoresistive effect element 112 is given by (1, 0, 0). A spherical surface 300 with the origin O (0, 0, 0) set at a center represents a surface over which the direction of the magnetization is movable. A point 301 represents the direction of the effective magnetic field. Before the current is applied to the magnetoresistive effect element 112, the magnetization vector in the second magnetic layer 102 is oriented toward the point 301 from the origin O and is held stationary. A locus 302 represents an orbit of the precession of the magnetization in the second magnetic layer 102 when a current flowing in the positive direction and having the first current density, which is not less than the critical current density for oscillation, is continuously applied to the magnetoresistive effect element 112 and a stable oscillating condition is obtained. A locus 303 represents an orbit of the precession of the magnetization in the second magnetic layer 102 when a current having the second current density is continuously applied to the magnetoresistive effect element 112 and a stable oscillating condition is obtained.

The magnetization in the first magnetic layer 101 is fixed in the direction 104. Starting from the state where the magnetization in the second magnetic layer 102 is oriented in the direction 105 of the effective magnetic field in the first step, the current flowing in the positive direction and having the first current density is applied to the magnetoresistive effect element 112 in the second step. As a result, the spin-transfer torque term is increased, and the direction of magnetization in the second magnetic layer 102 is rapidly changed toward the orbit denoted by the locus 302. Thus, the magnetization in the second magnetic layer 102 starts the precession on the locus 302 in a first oscillating condition where the action attributable to the spin-transfer torque term and the action attributable to the damping term, i.e., the second term in the right side of the equation (1), are balanced.

Next, a mechanism of transition from the first oscillating condition in the second step to a second oscillating condition in the third step in Embodiment 1 is described.

In the operation according to Embodiment 1, a current flowing in the positive direction and having the second current density, which is less than the critical current density for oscillation, is applied to the magnetoresistive effect element 112 as the third step. As a result, the spin-transfer torque is weakened, and the direction of magnetization in the second magnetic layer 102 is changed toward the point 301 representing the direction of the effective magnetic field. During a process of such a motion of the magnetization vector, the magnetization vector in the second magnetic layer 102 comes into the locus 303, i.e., a stable orbit when the current has the second current density, and the magnetoresistive effect element 112 is transited to the second oscillating condition (i.e., the condition where the action attributable to the spin-transfer torque term and the action attributable to the damping term are balanced).

A first transition time of the transition from the first oscillating condition where the precession is continued on the locus 302 to the second oscillating condition where the precession is continued on the locus 303 depends on the damping term, i.e., the second term in the right side of the equation (1), and further depends on the Gilbert damping constant α. In the case of a general magnetic substance, it is known that α is about 0.01 or more. Therefore, the damping action is large, and the first transition time is short.

In this embodiment, an effect of speeding up a rise of the oscillation of the magnetoresistive effect element 112 can be obtained by increasing a value of the first current density. When the first current density is 1.5 times or more the second current density, an effect of increasing the effect of shortening a rise time of the oscillation, which is obtained with the second step, in excess of the influence of an increase in the rise time of the oscillation due to the first transition time is more significant. To speed up the rise of the oscillation of the magnetoresistive effect element 112, therefore, the first current density is desirably 1.5 times or more the second current density.

Furthermore, when the magnetoresistive effect element 112 is stabilized in a magnetization reversal state where the magnetization in the second magnetic layer 102 of the magnetoresistive effect element 112 is oriented substantially in the same direction as the magnetization in the first magnetic layer, the first current density applied at not less than the critical current density for oscillation to the magnetoresistive effect element 112 in the second step is desirably smaller than the critical current density j_{R} for magnetization reversal. When a time during which the current having the first current density is applied to the magnetoresistive effect element 112 is shorter than a time during which the magnetization reversal occurs, the first current density may be not less than the critical current density j_{R} for magnetization reversal.

Thereafter, in the third step, the current having the second current density is continuously applied to the magnetoresistive effect element 112, and the oscillation is sustained at the frequency corresponding to the second current density.

The mechanism has been described above in connection with an oscillation mode in which the magnetization in the second magnetic layer 102 causes the precession substantially in a plane of the magnetoresistive effect element 112, but the oscillation mode is not limited to the above-described one. The above-described mechanism is similarly applied, for example, to the case where the magnetization in the second magnetic layer 102 causes the precession in a direction substantially perpendicular to the magnetoresistive effect element 112.

### Embodiment 2

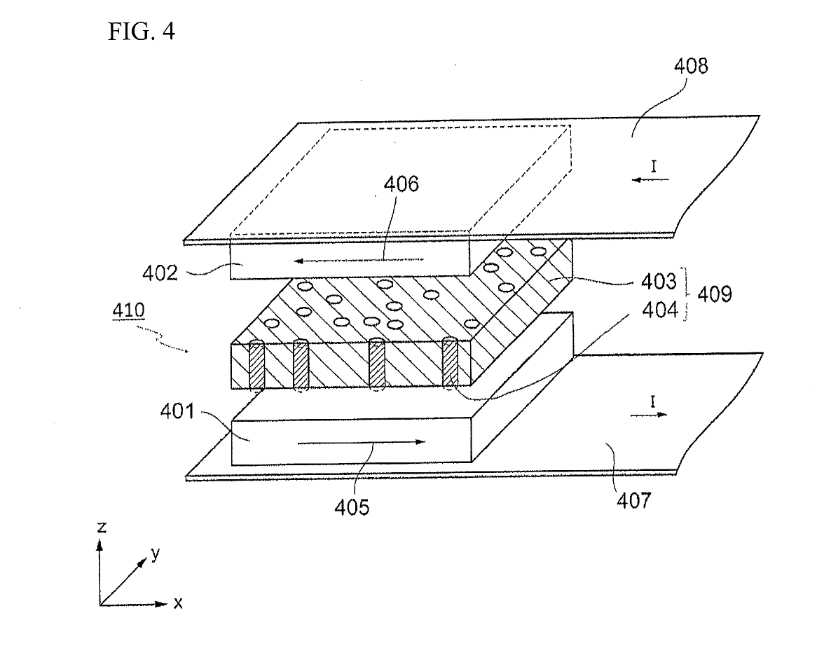

In a magnetoresistive effect oscillator 400 according to Embodiment 2, a magnetoresistive effect element 410 is used instead of the magnetoresistive effect element 112 in the magnetoresistive effect oscillator 100 according to Embodiment 1. The other configuration is the same as that of the magnetoresistive effect oscillator 100 according to Embodiment 1. FIG. 4 is a schematic view of the magnetoresistive effect element 410. The magnetoresistive effect element 410 includes a first magnetic layer 401, a second magnetic layer 402, and a spacer layer 409 arranged between them. A first electrode 407 is disposed in contact with the first magnetic layer 401, and a second electrode 408 is disposed in contact with the second magnetic layer 402, respectively. A current source 113 is connected between the electrode 407 and the electrode 408. A voltage source may be connected instead of the current source 113. The spacer layer 409 includes an insulating portion 403 and ferromagnetic nano-contact regions 404. The first magnetic layer 401, the second magnetic layer 402, and the ferromagnetic nano-contact regions 404 are each formed using a ferromagnetic substance and desirably made of, e.g., an alloy of Fe and Co, an alloy of Fe, Co and Al, or an alloy of Fe, Co, Al and Si. The insulating portion 403 is desirably made of a material having good electrical insulation, e.g., AlOx or MgO. Magnetizations in the first magnetic layer 401 and the second magnetic layer 402 are oriented in directions denoted by arrows 405 and 406, respectively, and magnetic domain walls are formed in the ferromagnetic nano-contact regions 404. An element having the above-mentioned structure is called an NCMR (nano-contact magnetoresistive effect) element. While the spacer layer 409 is actually in contact with the first magnetic layer 401 and the second magnetic layer 402 such that the first magnetic layer 401 and the second magnetic layer 402 are electrically connected to each other through the ferromagnetic nano-contact regions 404, the spacer layer 409 is illustrated in FIG. 4 in spaced relation from the first magnetic layer 401 and the second magnetic layer 402 for easier understanding of the structure of the spacer layer 409.

The direction of the arrow 406 is not limited to a direction opposed to that of the arrow 405, and it may be the same direction as that of the arrow 405 or an arbitrary direction between both the arrows.

An xy-plane is assumed to be a plane that is parallel to a film surface of the magnetoresistive effect element 410. A direction perpendicular to the film surface of the magnetoresistive effect element 410 is defined as the direction of a z-axis.

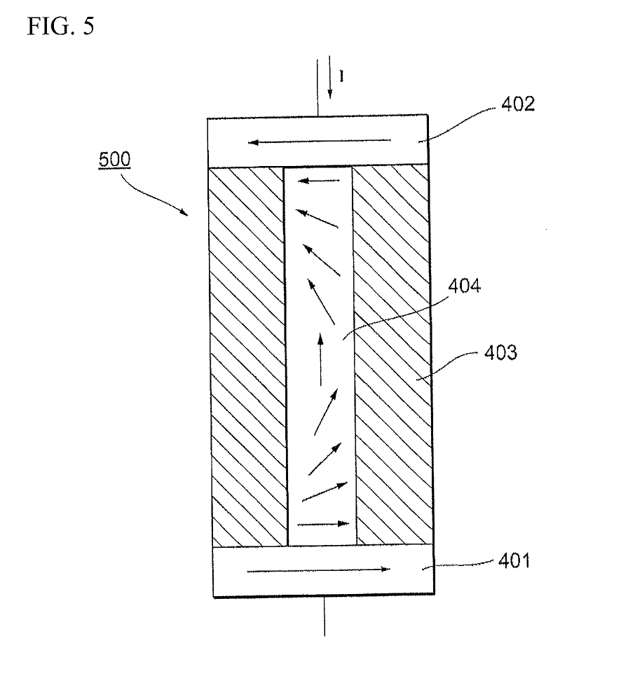

For the purpose of calculating an oscillation phenomenon of the magnetoresistive effect element 410, dynamics of a magnetic domain wall formed in one ferromagnetic nano-contact of the magnetoresistive effect element 410 are calculated. FIG. 5 illustrates a calculation model of the ferromagnetic nano-contact. In a modeling process, respective directions of magnetizations in the first magnetic layer 401 and the second magnetic layer 402 are assumed to be fixed. For example, an external magnetic field, exchange coupling with an antiferromagnetic substance, or a magnetic anisotropy can be utilized as a means for fixing the magnetic layers. The magnetic domain wall formed between the first magnetic layer 401 and the second magnetic layer 402 is assumed to be in the form in which magnetizations exchange-coupled with each other are one-dimensionally arranged in the z-axis direction from the first magnetic layer 401 toward the second magnetic layer 402.

In the calculation, the following equation slightly modified from the equation (1) is used.

$$\begin{matrix}[ Math . 4 ] & \\ \frac{\partial v}{\partial t} = - \vert γ \vert ( v \times {II}_{eff} ) + α ( v \times \frac{\partial v}{\partial t} ) + \frac{{μ}_{B} Pj}{e {M}_{S}} v \times ( \frac{\partial v}{\partial z} \times v ) & ( 4 )\end{matrix}$$

The effective magnetic field is assumed to be only an exchange magnetic field of which intensity is determined depending on an exchange coupling constant.

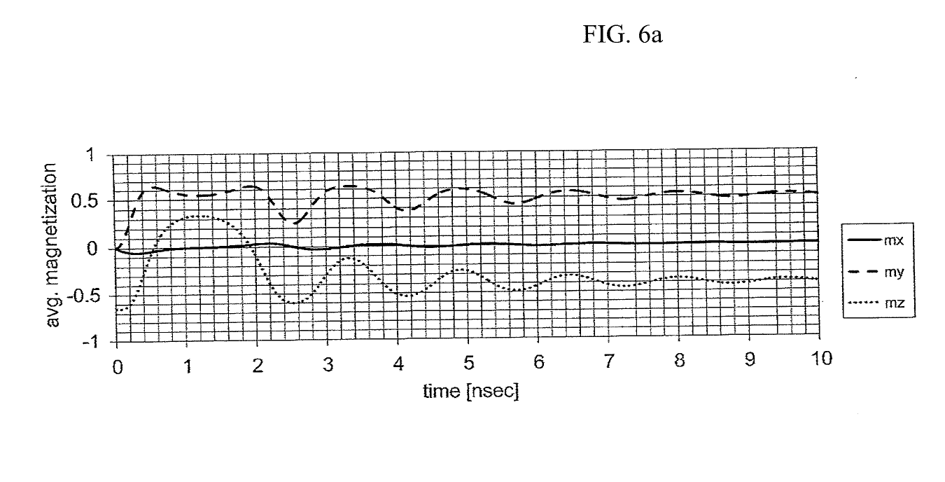

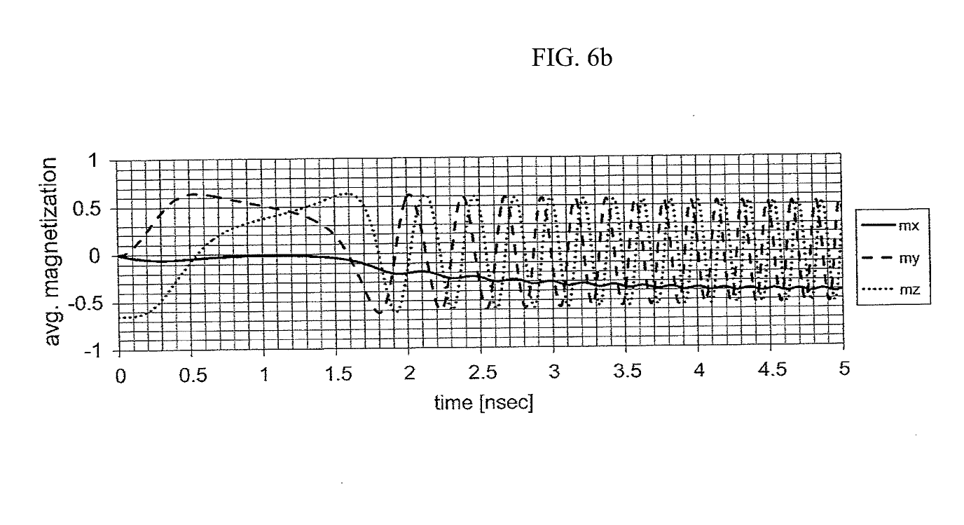

When a current I is applied to the magnetoresistive effect oscillator 410 through the electrodes to flow in the direction perpendicular to the individual layers, the spin-transfer torque acts on the magnetic domain wall, thus causing the magnetoresistive effect element 410 to oscillate. For the purpose of explanation, the following review is made on an assumption that the magnetization in the first magnetic layer 401 is fixed substantially in a direction of (1, 0, 0), and that the magnetization in the second magnetic layer 402 is fixed substantially in a direction of (−1, 0, 0). In the ferromagnetic nano-contact, the magnetic domain wall is formed by the magnetization of which direction is gradually changed from the direction of (1, 0, 0) toward the direction of (−1, 0, 0). FIG. 6b represents the calculation results of time-dependent changes of average values of individual components of a magnetization vector in the ferromagnetic nano-contact when a current having the critical current density for oscillation is applied to the magnetoresistive effect element 410. When an average value m_{y} of a y-component of the magnetization vector is zero, the magnetic domain wall in the ferromagnetic nano-contact is a Neel wall, and when an average value m_{z} of a z-component is zero, the magnetic domain wall is a Bloch wall. After 2.5 nanoseconds (nsec), the magnetization vector vibrates while m_{y} and m_{z} alternately take zero. In other words, the magnetization in the ferromagnetic nano-contact periodically causes precession. Thus, there occurs a phenomenon that the Neel wall and the Bloch wall alternately transit from one to the other. Because those two magnetic domain walls have different resistance values, resistance vibrates and oscillation occurs.

In this embodiment, as in the magnetoresistive effect oscillator 100 according to Embodiment 1, a drive current can be generated by a circuit illustrated as the circuit diagram of FIG. 2a, for example. Moreover, in this embodiment, as in the magnetoresistive effect oscillator 200 according to Embodiment 1, the drive current can be generated by a circuit illustrated as the circuit diagram of FIG. 2b, for example.

In this embodiment, as in Embodiment 1, the magnetoresistive effect element can be more stably operated in the first step than that disclosed in PTL 1.

While the directions of magnetizations in the first magnetic layer 401 and the second magnetic layer 402 are assumed to be fixed in this embodiment, an embodiment is not limited to that case. For example, even when the second magnetic layer is a magnetization free layer in which the direction of magnetization is not fixed, it is also possible to more stably operate the magnetoresistive effect element in the first step.

### Example 1

The magnetoresistive effect oscillator 400 of EXAMPLE 1 includes the magnetoresistive effect element 410 including the first magnetic layer 401, the second magnetic layer 402, and the spacer layer 409 arranged between them. The first electrode 407 is disposed to be electrically connected to the first magnetic layer 401, and the second electrode 408 is disposed to be electrically connected to the second magnetic layer 402. The current source 113 is connected between the first electrode 407 and the second electrode 408. The spacer layer 409 includes the insulating portion 403 and the ferromagnetic nano-contact regions 404. The first magnetic layer 401, the second magnetic layer 402, and the ferromagnetic nano-contact regions 404 are each made of Fe₅₀Co₅₀. The ferromagnetic nano-contact region 404 has a length of 40 nm and a diameter of 20 nm. The insulating layer 403 is made of Al₂O₃ as a main component. An antiferromagnetic layer made of Ir₂₀Mn₈₀ is positioned immediately under the first magnetic layer 401 in contact therewith, and is exchange-coupled with the first magnetic layer 401. As a result, the magnetization in the first magnetic layer 401 is fixed and oriented in the direction of the arrow 405. The magnetization in the second magnetic layer 402 is fixed and oriented in the direction of the arrow 406 by an externally applied magnetic field. Because the directions of the arrow 405 and the arrow 406 are not parallel, a magnetic domain wall is formed in the ferromagnetic nano-contact region 404. When the current I is applied to the magnetoresistive effect element 410 through the electrodes to flow in a direction perpendicular to the individual layers, the spin-transfer torque acts on the magnetic domain wall, thus generating a microwave.

A modeling process similar to that in Embodiment 2 is employed to calculate an oscillation phenomenon of the magnetoresistive effect oscillator 400.

Table 1 lists parameters used in the calculation.

TABLE 1

| Symbol | Meaning | Value | Unit |
|---|---|---|---|
| γ | Gyromagnetic ratio | 2.2176 × 10⁵ | m/(A · sec) |
| α | Gilbert damping constant | 0.02 | — |
| A | Exchange coupling constant | 1.3 × 10⁻¹¹ | J/m |
| Ms | Saturated magnetization | 8 × 10⁵ | A/m |
| P | Spin polarization efficiency | 1 | — |

In EXAMPLE 1, the applied current density is assumed to be a value in one ferromagnetic nano-contact.

The applied current density can be estimated by the following method. The method includes the steps of making the spacer layer of the magnetoresistive effect element 410 exposed, observing the exposed surface by a conductive atomic force microscopy (c-AFM), and evaluating a total area of the nano-contact in the exposed surface from a conductive region. The current density in the nano-contact can be estimated by dividing a current value applied to the magnetoresistive effect element 410 by the total area of the nano-contact.

The critical current density for oscillation of the magnetoresistive effect element 410 was determined as follows through calculation. Behavior of the magnetization in the ferromagnetic nano-contact in a steady state was calculated by applying a constant current in the positive direction, starting from a state where no current was applied to the magnetoresistive effect element 410. FIGS. 6a and 6b represent the calculation results of time-dependent changes of an average value of the magnetization in the ferromagnetic nano-contact. FIG. 6a represents the result when a current flowing in the positive direction and having the current density of 8.6×10¹⁰ A/m² was applied. In the steady state, the magnetization in the ferromagnetic nano-contact was held stationary. On the other hand, FIG. 6b represents the result when a current flowing in the positive direction and having the current density of 8.7×10¹⁰ A/m² was applied. In the steady state, the Neel wall and the Bloch wall were alternately transited from one to the other at a constant period, and the magnetization in the ferromagnetic nano-contact caused stable precession. Accordingly, the critical current density for oscillation was about 8.7×10¹⁰ A/m².

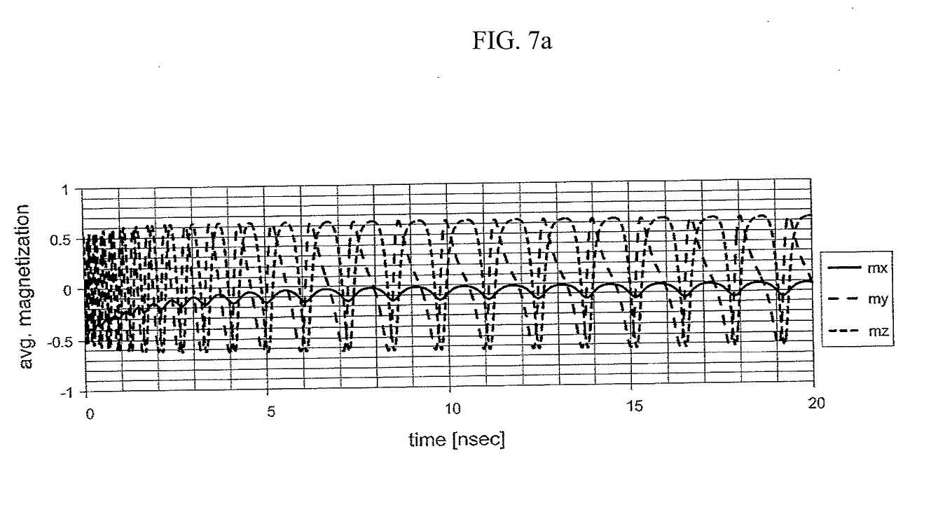

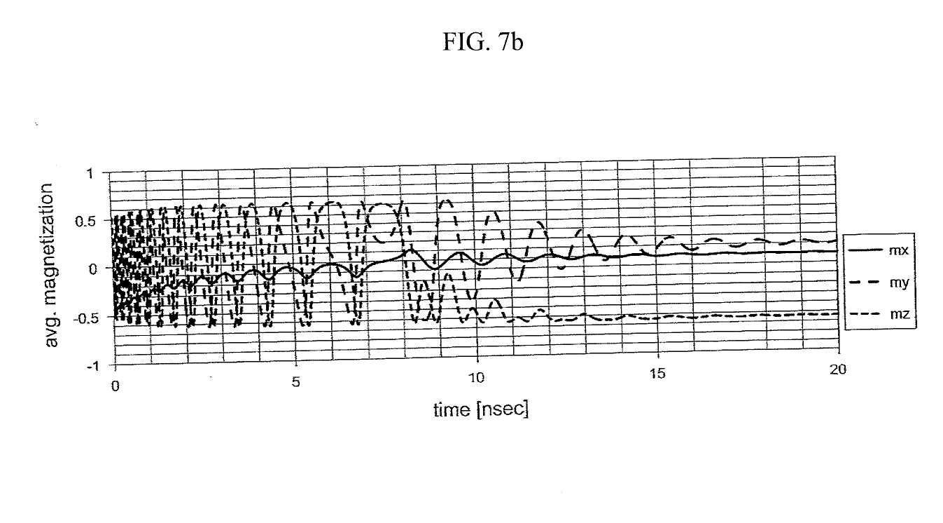

A range of the current density in which the operating point of the magnetoresistive effect element 410 was positioned in the region of bistability was calculated by the following method. Through simulation, a current flowing in the positive direction and having the critical current density for oscillation, i.e., 8.7×10¹⁰ A/m², was first applied to the magnetoresistive effect element 410, and the applied current density was then gradually reduced from a steady state little by little, to thereby determine the current density at which the static condition was obtained in a steady state. FIG. 7a represents time-dependent change of the magnetization when a current flowing in the positive direction and having the current density of 1.9×10¹⁰ A/m² was applied. As seen from FIG. 7a, the oscillation was sustained. On the other hand, FIG. 7b represents time-dependent change of the magnetization when a current flowing in the positive direction and having the current density of 1.8×10¹⁰ A/m² was applied. After 8 nsec, rotation of the magnetic domain wall was stopped, and the oscillation disappeared. Thus, the critical current density for stationary is about 1.8×10¹⁰ A/m², and the operating point of the magnetoresistive effect element 410 is positioned in the region of bistability when a current flowing in the positive direction and having the current density of not less than 1.9×10¹⁰ A/m² and less than 8.7×10¹⁰ A/m² is applied to the magnetoresistive effect element 410.

A rise time of the oscillation is defined as a time from the start of application of a current to the magnetoresistive effect element 410 for the rise of the oscillation until fluctuations of an oscillation frequency are reduced to 1% or less of the oscillation frequency in the steady state. In EXAMPLE 1 and later-described EXAMPLE 2, the time of starting the application of the current to the magnetoresistive effect element for the rise of the oscillation is set to 0 sec.

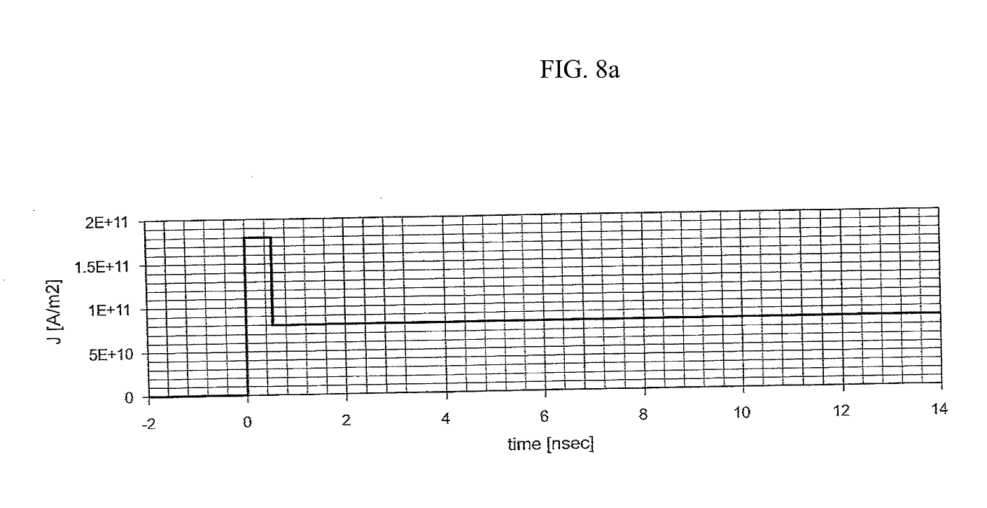

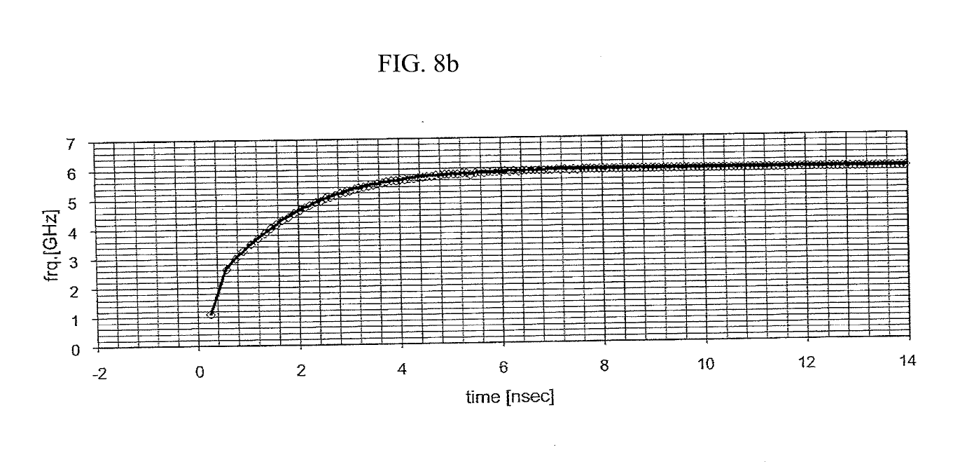

The operation of the current source 113 in EXAMPLE 1 is described below. FIG. 8a is a graph representing time-dependent change of the applied current in EXAMPLE 1. Starting from the state where no current was applied to the magnetoresistive effect element 410 as the first step, a current flowing in the positive direction and having the current density of 18.0×10¹⁰ A/m² was applied for 0.5 nsec as the second step. Thereafter, a current flowing in the positive direction and having the current density of 8.0×10¹⁰ A/m² was applied as the third step to make the operating point of the magnetoresistive effect element 410 positioned in the region of bistability.

FIG. 8b is a graph representing time-dependent change of the oscillation frequency obtained in EXAMPLE 1. The oscillation occurred at a constant frequency of about 6 GHz in the steady state, and the rise time was 6.5 nsec.

### Example 2

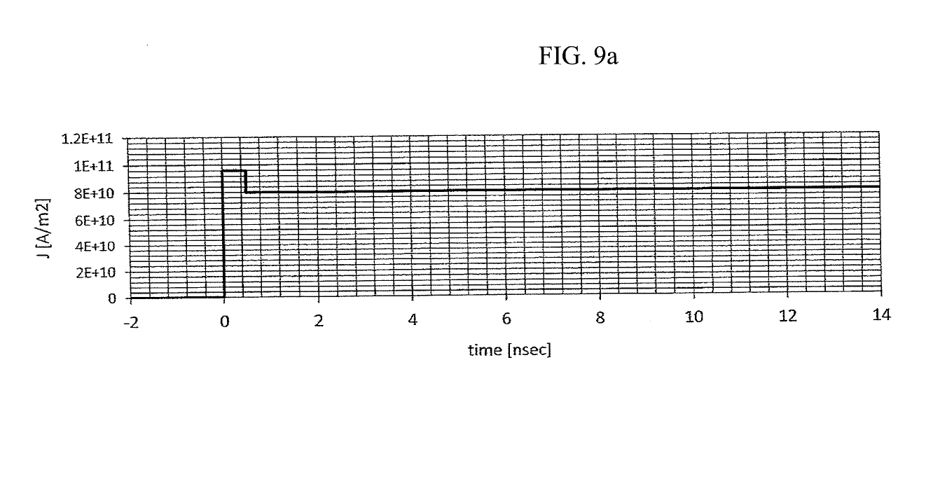

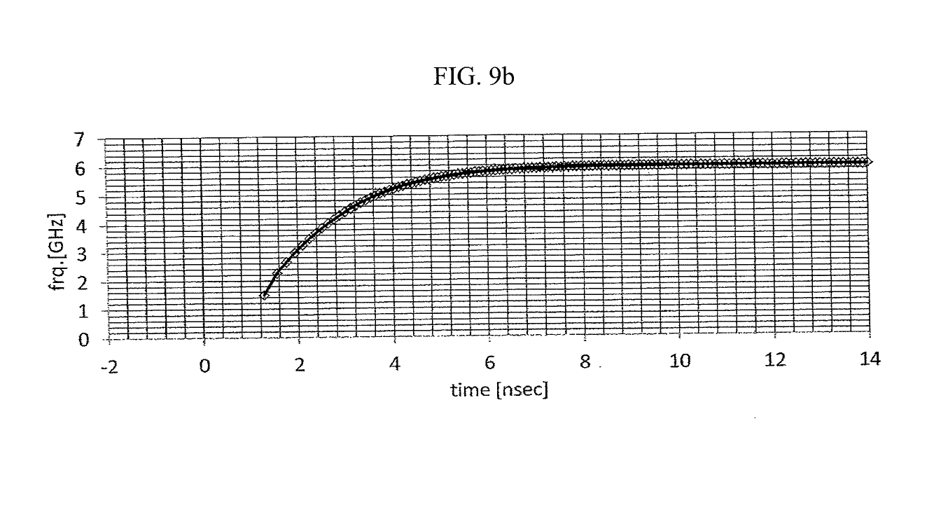

EXAMPLE 2 represents the case where a current having the current density of 9.6×10¹⁰ A/m² is applied to the magnetoresistive effect element in the second step of EXAMPLE 1. A magnetoresistive effect oscillator of EXAMPLE 2 is the same as that of EXAMPLE 1 except for the operation of the current source 113. FIG. 9a depicts time-dependent change of the current density applied to the magnetoresistive effect element 410 in EXAMPLE 2. Starting from the state where no current was applied to the magnetoresistive effect element 410 as the first step, a current flowing in the positive direction and having the current density of 9.6×10¹⁰ A/m² was applied for 0.5 nsec as the second step. Thereafter, a current flowing in the positive direction and having the current density of 8.0×10¹⁰ A/m² was applied as the third step to make the operating point of the magnetoresistive effect element 410 positioned in the region of bistability.

FIG. 9b depicts time-dependent change of the oscillation frequency of the magnetoresistive effect element 410 in EXAMPLE 2. The oscillation frequency gradually increased, and the magnetoresistive effect element 410 finally caused stable oscillation at a constant frequency of about 6 GHz. The rise time was about 8 nsec.

Comparing the oscillation rise times in EXAMPLE 1 and EXAMPLE 2, the oscillation rise time is 6.5 nsec in EXAMPLE 1, whereas it is 8 nsec in EXAMPLE 2. As seen from that result, an effect of speeding up the rise of the oscillation of the magnetoresistive effect element can be obtained by increasing the current density applied in the second step.

The magnetoresistive effect oscillator according to the present invention can be utilized in high-speed wireless communications.

### REFERENCE SIGNS LIST

100 . . . magnetoresistive effect oscillator, 101, 102 . . . magnetic layers, 103 . . . spacer layer, 106 . . . conduction electron, 110, 111 . . . electrodes, 112 . . . magnetoresistive effect element, 113 . . . current source, 114 . . . current applying unit, 115 . . . control unit, 201 . . . inductor, 202 . . . resistance, 204 . . . current source, 205 . . . current applying unit, 400 . . . magnetoresistive effect oscillator, 401, 402 . . . magnetic layers, 403 . . . insulating portion, 404 . . . ferromagnetic nano-contact region, 407, 408 . . . electrodes, 409 . . . spacer layer, 410 . . . magnetoresistive effect element, 500 . . . calculation model of ferromagnetic nano-contact, 1001 . . . region where only oscillating condition is stable, 1002 . . . region of bistability, 1003, 1004 . . . regions where only stationary condition is stable

What is claimed is:

1. A magnetoresistive effect oscillator comprising:
a magnetoresistive effect element including a first magnetic layer, a second magnetic layer, and a spacer layer sandwiched between the first magnetic layer and the second magnetic layer; and
a current applying unit that applies a current to the magnetoresistive effect element to make the magnetoresistive effect element oscillate at a predetermined oscillation frequency,
wherein, starting from a state of an operating point of the magnetoresistive effect element being in a region where only a static condition is stabilized,
the current applying unit applies a current, which has a first current density not less than a critical current density for oscillation of the magnetoresistive effect element, to the magnetoresistive effect element,
and then applies a current having a second current density to the magnetoresistive effect element to make the operating point of the magnetoresistive effect element positioned in a region of bistability such that the magnetoresistive effect element oscillates at a predetermined frequency, and
a direction of the current having the second current density being same as a direction of the current having the first current density.
